(19) United States
(12) Patent Application Publication
(10) Pub. No.: US 2023/0040885 A1
(43) Pub. Date: Feb. 9, 2023

(54) EXCLUSION RING WITH FLOW PATHS FOR EXHAUSTING WAFER EDGE GAS

(71) Applicant: Lam Research Corporation, Fremont, CA (US)

(72) Inventors: Vinayakaraddy Gulabal, Yadgir (IN); Eric H. Lenz, Livermore, CA (US); Ravi Vellanki, San Jose, CA (US)

(21) Appl. No.: 17/758,797

(22) PCT Filed: Jan. 13, 2021
(86) PCT No.: PCT/US2021/013327

§ 371 Date: Jul. 13, 2022

Related U.S. Application Data
(60) Provisional application No. 62/962,875, filed on Jan. 17, 2020.

(51) Int. Cl. H01J 37/32; C23C 16/458; C23C 16/50; C23C 16/455; H01L 21/687

(52) U.S. Cl. CPC H01J 37/32642; C23C 16/4585; C23C 16/50; C23C 16/45544; C23C 16/45536; H01J 37/3244; H01J 37/32834; H01L 21/68721; H01J 2237/332

(57) ABSTRACT

An exclusion ring for semiconductor wafer processing includes an outer circumferential segment having a first thickness and an inner circumferential segment having a second thickness, with the first thickness being greater than the second thickness. The top surface of an inner circumferential segment and the top surface of the outer circumferential segment define a common top surface for the exclusion ring. A plurality of flow paths is formed within the outer circumferential segment, with each of the flow paths extending radially through the plurality of flow paths provides for exhaust of a wafer edge gas from the pocket where a wafer has an edge thereof disposed below part of the inner circumferential portion. The exhausting of the wafer edge gas from the pocket prevents up-and-down movement of the exclusion ring when bowed wafers are processed.

### RELATED APPLICATIONS

A PCT request form is filed concurrently with this specification as part of the present application. Each application that the present application claims benefit of or priority to as identified in the concurrently filed PCT request form is incorporated by reference herein in its entirety and for all purposes.

### BACKGROUND

In semiconductor fabrication, layers of dielectric (insulating) and metal (conducting) materials are created using deposition processes. For example, chemical vapor deposition (CVD) and atomic layer deposition (ALD) are used to deposit a metal, e.g., tungsten, to form conductive features such as contacts, vias, and plugs on a chip.

In some semiconductor fabrication processes, an exclusion ring that overlaps the exterior edge of a semiconductor wafer may be used to reduce or minimize edge non-uniformities that may occur during such processing.

### SUMMARY

Details of one or more implementations of the subject matter described in this specification are set forth in the accompanying drawings and the description below. Other features, aspects, and advantages will become apparent from the description, the drawings, and the claims.

In some implementations, an exclusion ring for use in processing semiconductor wafers is provided that includes an outer circumferential segment with a top surface and a bottom surface in which a distance between the top surface of the outer circumferential segment and the bottom surface of the outer circumferential segment defines a first thickness of the exclusion ring. The exclusion ring may also include an inner circumferential segment with a top surface and a bottom surface, as well as one or more transition surfaces that span between the bottom surface of the outer circumferential segment and the bottom surface of the inner circumferential segment. A distance between the top surface of the inner circumferential segment and the bottom surface of the inner circumferential segment may define a second thickness of the exclusion ring, the first thickness of the exclusion ring may be greater than the second thickness of the exclusion ring, and a plurality of flow paths may be formed within the outer circumferential segment. Each flow path of the plurality of flow paths may extend from the one or more transition surfaces, through the outer circumferential segment of the exclusion ring, and to an exterior perimeter of the exclusion ring, and the flow paths may be spaced apart from one another along a periphery of the outer circumferential segment of the exclusion ring.

In some implementations, the exclusion ring may further include a plurality of ears. Each of the ears may extend from the outer circumferential segment of the exclusion ring and may have a top surface and a bottom surface. The exclusion ring may also have a plurality of fingers; each of the fingers may be attached to a respective one of the plurality of ears.

In some implementations, the plurality of ears may include three ears that are substantially evenly spaced around the outer circumferential segment of the exclusion ring. The plurality of flow paths may include a number of flow paths, e.g., from three to sixteen, between each of the three ears.

In some such implementations, the same number of flow paths may be formed through the outer circumferential segment between each of the three ears.

In some further such implementations, there may be seven to fourteen flow paths formed through the outer circumferential segment between each of the three ears.

In some implementations, the flow paths that are proximate to each of the three ears may be sized larger than the flow paths that are not proximate to any of the three ears.

In some implementations, the inner circumferential segment may an innermost edge that is axisymmetric about a center axis and a total cross-sectional area of the flow paths in a first reference plane that is perpendicular to the center axis and interposed between the bottom surfaces of the inner circumferential segment and the outer circumferential segment may be in a range from about 16% to about 20% of a total ring bottom surface area that is defined between the outer perimeter of the exclusion ring and a reference circle that circumscribes the one or more transition surfaces.

In some implementations, the total cross-sectional area of the flow paths in the first reference plane may be in a range from about 23% to about 28% of the total ring bottom surface area.

In some implementations, the total cross-sectional area of the flow paths in the first reference plane may be in a range from about 35% to about 43% of the total ring bottom surface area.

In some implementations, each of the flow paths may be either a channel in the bottom surface of the outer circumferential segment or an enclosed passage through the outer circumferential segment.

In some implementations, an exclusion ring may be provided that includes an inner circumferential portion and an outer circumferential portion integral with the inner circumferential portion. The outer circumferential portion may have a first thickness that is greater than a second thickness of the inner circumferential portion, and a bottom surface of the outer circumferential portion may be configured to be placed over a pedestal when installed in a plasma processing tool. The inner circumferential portion may be configured to be spaced apart from the pedestal of the plasma processing tool when the bottom surface of the outer circumferential portion is resting on the pedestal of the plasma processing tool, thereby defining a pocket in between the pedestal and the exclusion ring that permits an edge of a wafer, when present, to be disposed in between part of the inner circumferential portion and the pedestal. The outer circumferential portion may include a plurality of flow paths, each flow path extending from one or more transition surfaces that span between the bottom surface of the outer circumferential portion and a bottom surface of the inner circumferential portion, through the outer circumferential portion, and to an outer perimeter of the exclusion ring to provide for exhaust of a wafer edge gas from the pocket.

In some implementations, the exclusion ring may further include a plurality of ears, with each of the ears extending from the outer circumferential portion of the exclusion ring, and a plurality of fingers, in which each of the fingers is attached to a respective one of the plurality of ears.

In some such implementations, the plurality of ears may include three ears, the three ears may be substantially evenly spaced around the outer circumferential portion of the exclusion ring, and the plurality of flow paths may include a number of flow paths between each of the three ears.

In some implementations, the flow paths proximate to each of the three ears may be sized larger than the flow paths that are not proximate to any of the three ears.

In some implementations, the plurality of flow paths may be configured to exhaust about 10% to about 30% of the wafer edge gas from the pocket toward a chamber wall of the plasma processing tool such that a remainder of the wafer edge gas is directed toward the edge of the wafer when the wafer is present in the pocket and the wafer edge gas is flowing.

In some implementations, the plurality of flow paths may be configured to exhaust about 40% to about 60% of the wafer edge gas from the pocket toward a chamber wall of the plasma processing tool such that a remainder of the wafer edge gas is directed toward the edge of the wafer when the wafer is present in the pocket and the wafer edge gas is flowing.

In some implementations, the plurality of flow paths may be configured to exhaust about 70% to about 90% of the wafer edge gas from the pocket toward a chamber wall of the plasma processing tool such that a remainder of the wafer edge gas is directed toward the edge of the wafer when the wafer is present in the pocket and the wafer edge gas is flowing.

In some implementations, each of the flow paths may be either a channel in the bottom surface of the outer circumferential portion or an enclosed passage through the outer circumferential portion.

In some implementations, a method of processing a wafer in a plasma processing tool may be provided. The method may include positioning an exclusion ring such that an outer circumferential portion of the exclusion ring sits on a pedestal of a chamber and an inner circumferential portion of the exclusion ring is spaced apart from the pedestal to define a pocket where a wafer has an edge thereof disposed below part of the inner circumferential portion, supplying a wafer edge gas into the pocket during plasma processing of the wafer such that a portion of the wafer edge gas is directed toward the wafer, and exhausting a portion of the wafer edge gas from the pocket toward the chamber through a plurality of flow paths that extend through the outer circumferential portion of the exclusion ring.

In some implementations, the plurality of flow paths may be configured to exhaust an amount of wafer edge gas from the pocket toward the chamber, with a remaining portion of the wafer edge gas being directed toward the wafer. The amount of wafer edge gas may be about 10% to about 30% of the wafer edge gas, about 40% to 60% of the wafer edge gas, or about 70% to about 90% of the wafer edge gas.

In an example embodiment, an exclusion ring may include an outer circumferential segment having a top surface and a bottom surface, with a distance between the top surface and the bottom surface of the outer circumferential segment defining a first thickness of the exclusion ring. The exclusion ring may also include an inner circumferential segment having a top surface and a bottom surface, with the top surface of the inner circumferential segment and the top surface of the outer circumferential segment defining a common top surface for the exclusion ring. The distance between the top surface and the bottom surface of the inner circumferential segment may define a second thickness of the exclusion ring, with the first thickness of the exclusion ring being greater than the second thickness of the exclusion ring. The exclusion ring may further include a plurality of slots formed within the outer circumferential segment, with each of the plurality of slots extending radially through the outer circumferential segment of the exclusion ring at a bottom surface of the outer circumferential segment. The plurality of slots may be spaced apart along a periphery of the outer circumferential segment of the exclusion ring.

In one embodiment, the exclusion ring may further include a plurality of ears and a plurality of fingers. Each of the ears may extend from the outer circumferential segment of the exclusion ring and may have a top surface and a bottom surface. Each of the fingers may be attached to a respective one of the plurality of ears. In one embodiment, the plurality of ears may include three ears, and the three ears may be substantially evenly spaced around the outer circumferential segment of the exclusion ring. In one embodiment, the plurality of slots may include a number of slots between each of the three ears, with the number of slots being in a range from three to sixteen.

In one embodiment, the same number of slots may be formed along the bottom surface of the outer circumferential segment between each of the three ears. In one embodiment, seven to fourteen slots may be formed along the bottom surface of the outer circumferential segment between each of the three ears. In one embodiment, the slots adjacent to one of the three ears may have a size larger than the size of the non-adjacent slots.

In one embodiment, the total ring bottom surface area may include an area defined by the bottom surface of each of the three ears, plus an area defined by the bottom surface of the outer circumferential segment that remains after formation of the plurality of slots, plus an area of the bottom surface of the outer circumferential segment that has been removed to form the plurality of slots. In one embodiment, the area of the bottom surface of the outer circumferential segment that has been removed to form the plurality of slots may be in a range from about 16% to about 20% of the total ring bottom surface area. In another embodiment, the area of the bottom surface of the outer circumferential segment that has been removed to form the plurality of slots may be in a range from about 23% to about 28% of the total ring bottom surface area. In yet another embodiment, the area of the bottom surface of the outer circumferential segment that has been removed to form the plurality of slots may be in a range from about 35% to about 43% of the total ring bottom surface area.

In another example embodiment, an exclusion ring may include an inner circumferential portion and an outer circumferential portion that is integral with the inner circumferential portion. The outer circumferential portion may have a first thickness that is greater than a second thickness of the inner circumferential portion. A bottom surface of the outer circumferential portion may be configured to sit over a pedestal when installed in a plasma processing tool, and the inner circumferential portion may be configured to be spaced apart from the pedestal to define a pocket where a wafer when present has an edge thereof disposed below part of the inner circumferential portion. The bottom surface of the outer circumferential portion may be configured to have a plurality of slots extending radially through the outer circumferential portion, such that each of the plurality of slots forms a gas flow path that provides for exhaust of a wafer edge gas from the pocket.

In one embodiment, the exclusion ring may further include a plurality of ears and a plurality of fingers. Each of the ears may extend from the outer circumferential portion of the exclusion ring and may have a top surface and a bottom surface. Each of the fingers may be attached to a respective one of the plurality of ears. In one embodiment, the plurality of ears may include three ears, and the three ears may be substantially evenly spaced around the outer circumferential portion of the exclusion ring. In one embodiment, the plurality of slots may include a number of slots between each of the three ears. In one embodiment, the slots adjacent to one of the three ears may have a size larger than a size of the non-adjacent slots.

In one embodiment, the plurality of slots may be configured to exhaust about 10% to about 30% of the wafer edge gas from the pocket toward the walls of a chamber of the plasma processing tool such that a remainder of the wafer edge gas is directed toward a wafer when present in the plasma processing tool. In one embodiment, the plurality of slots may be configured to exhaust about 40% to about 60% of the wafer edge gas from the pocket toward the walls of a chamber of the plasma processing tool such that a remainder of the wafer edge gas is directed toward a wafer when present in the plasma processing tool. In one embodiment, the plurality of slots may be configured to exhaust about 70% to about 90% of the wafer edge gas from the pocket toward the walls of a chamber of the plasma processing tool such that a remainder of the wafer edge gas is directed toward a wafer when present in the plasma processing tool.

In yet another example embodiment, a method of processing a wafer in a plasma processing tool may be provided that includes positioning an exclusion ring over a pedestal of a chamber. In one embodiment, the exclusion ring may be positioned such that an outer circumferential portion of the exclusion ring sits over a pedestal of a chamber and an inner circumferential portion of the exclusion ring is spaced apart from the pedestal to define a pocket where a wafer has an edge thereof disposed below part of the inner circumferential portion. The method may also include supplying a wafer edge gas into the pocket during plasma processing of the wafer such that a portion of the wafer edge gas is directed toward the wafer. In one embodiment, the wafer edge gas may be fed into the pocket through an edge gas groove formed in the pedestal. The method may further include exhausting a portion of the wafer edge gas from the pocket toward the chamber through a plurality of slots that extend through the outer circumferential portion of the exclusion ring.

In one embodiment, the plurality of slots may be configured to exhaust about 10% to about 30% of the wafer edge gas from the pocket toward the walls of a chamber, with a remaining portion of the wafer edge gas being directed toward the wafer. In one embodiment, the plurality of slots may be configured to exhaust about 40% to about 60% of the wafer edge gas from the pocket toward the walls of the chamber, with a remaining portion of the wafer edge gas being directed toward the wafer. In one embodiment, the plurality of slots may be configured to exhaust about 70% to about 90% of the wafer edge gas from the pocket toward the walls of a chamber, with a remaining portion of the wafer edge gas being directed toward the wafer

Other aspects and advantages of the disclosures herein will become apparent from the following detailed description, taken in conjunction with the accompanying drawings, which illustrate by way of example the principles of the disclosures.

### BRIEF DESCRIPTION OF THE DRAWINGS

FIG. 1 is a simplified schematic diagram that illustrates an example substrate processing system which may be used to process a wafer.

FIGS. 2A-2C are simplified schematic diagrams illustrating a problem that has been observed in the processing of bowed wafers.

FIG. 3 is a simplified schematic diagram that shows an example exclusion ring with a slot formed in the outer portion of the exclusion ring, in accordance with one embodiment.

FIG. 4 is a simplified cross-sectional diagram of an example exclusion ring with a slot formed in the outer portion of the exclusion ring, in accordance with one embodiment.

FIG. 5A is a top view of an example exclusion ring having a plurality of slots formed within the outer circumferential portion thereof, in accordance with one embodiment.

FIG. 5B is a bottom view of an example exclusion ring having a plurality of slots formed within the outer circumferential portion thereof, in accordance with one embodiment.

FIG. 6 is a bottom view of an example exclusion ring that illustrates how the total ring bottom surface area is determined, in accordance with an example embodiment.

FIG. 7a is a simplified partial front view of the slots formed within the outer circumferential portion of an example exclusion ring, in accordance with one embodiment.

FIG. 7b is a simplified partial front view of enclosed passages formed within the outer circumferential portion of another example exclusion ring.

FIGS. 8A-8D illustrate the use of an example exclusion ring in a multi-station plasma processing tool, in accordance with one embodiment.

FIG. 8E depicts a perspective view of the underside of an example exclusion ring.

FIG. 9 is a simplified cross-sectional diagram that shows additional details of an example exclusion ring with a slot formed in the outer portion of the exclusion ring, in accordance with one embodiment.

### DETAILED DESCRIPTION

In the following description, numerous specific details are set forth in order to provide a thorough understanding of the example embodiments. However, it will be apparent to one skilled in the art that the example embodiments may be practiced without some of these specific details. In other instances, process operations and implementation details have not been described in detail, if already well known.

In the processing of bowed wafers, the wafer edge can contact the exclusion ring and cause the exclusion ring to vibrate up and down when the wafer edge gas starts to flow. The gas flow of the wafer edge gas between the exclusion ring and the wafer is hindered by the contact between the wafer edge and the exclusion ring. This causes the wafer edge gas to accumulate within a pocket around the wafer that is defined between the pedestal supporting the exclusion ring, the exclusion ring, and the bowed wafer. The accumulated wafer edge gas eventually reaches sufficient pressure that some of the wafer edge gas may periodically flow radially outward through the area where the pedestal contacts the exclusion ring in order to relieve the pressure. This has the effect of causing the exclusion ring (and possibly the wafer) to vibrate up and down. Such up-and-down movement of the exclusion ring during processing is problematic because it results in unwanted bevel and backside deposition, as well as potentially undesirable particulate generation. Embodiments of the present invention provide an exclusion ring having a plurality of flow paths, e.g., in the form of a plurality of slots, which leaks the gases that flow at the edge of the wafer, e.g., wafer edge gases, outward, away from the wafer center. During processing of bowed wafers, when the wafer edge gas starts to flow, the wafer edge gas does not cause the exclusion ring having the undercut to vibrate up and down because some of the gas is leaked outward via the flow paths, thereby avoiding the above-discussed issue. As such, unwanted bevel and backside deposition is avoided during processing of bowed wafers.

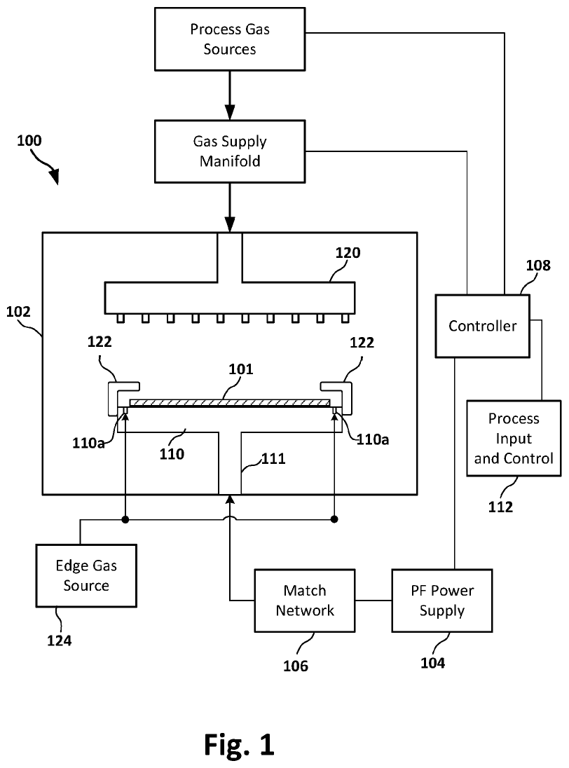

FIG. 1 is a simplified schematic diagram that illustrates a substrate processing system 100 which may be used to process a wafer 101. The system may include chamber 102, which can include an upper chamber body and a lower chamber body, that encloses a volume, at least in part, using one or more chamber walls. A center column 111 may be configured to support a pedestal 110, which in one embodiment may be a powered electrode. The pedestal 110 may be electrically coupled to radio frequency (RF) power supply 104 via a match network 106. The RF power supply may be controlled by a controller 108, which may be configured to operate the substrate processing system 100 by executing process input and control 112 instructions. The process input and control can include information or instructions defining process recipes, such as power levels, timing parameters, process gases, mechanical movement of the wafer 101, etc., to deposit or form films over the wafer 101 via atomic layer deposition (ALD) methods or plasma-enhanced chemical vapor deposition (PECVD) methods (or to remove or etch material from the wafer in etch-based systems).

The substrate processing system 100 may further include a gas supply manifold 114 that may be connected to process gas sources 116, e.g., gas chemistry supplies from a facility. Depending on the processing being performed, the controller 108 may control the delivery of process gases via the gas supply manifold 114. The selected gases may then be flowed into the showerhead 120 and distributed in the volume of space defined between the showerhead 120 and the wafer 101 and disposed over the pedestal 110. Appropriate valves and mass flow control mechanisms may be employed to ensure that the proper gases are delivered during the deposition and plasma treatment phases of the process. The process gases may exit the chamber 102 via an outlet. A vacuum pump may draw process gases out of the chamber 102 via the outlet and maintain a suitably low pressure within the chamber for processing.

Also shown in FIG. 1 is an exclusion ring 122′ that may encircle an outer region of a wafer placed on the pedestal 110. The exclusion ring 122′ may serve to prevent deposition on the edge bevel of the wafer 101 and the backside of the wafer 101 during processing, as will be described in more detail below. The pedestal 110 may also include an edge gas groove 110a, which may be configured to surround the outer periphery of wafer 101 disposed over the pedestal 110. The edge gas groove 110a may be in flow communication with edge gas source 124, which may typically be a source of an inert gas such as, for example, argon (Ar). During processing, an edge gas may be flowed through the edge gas groove 110a into the space defined between the exclusion ring 122′ and the pedestal 110, as will be described in more detail below.

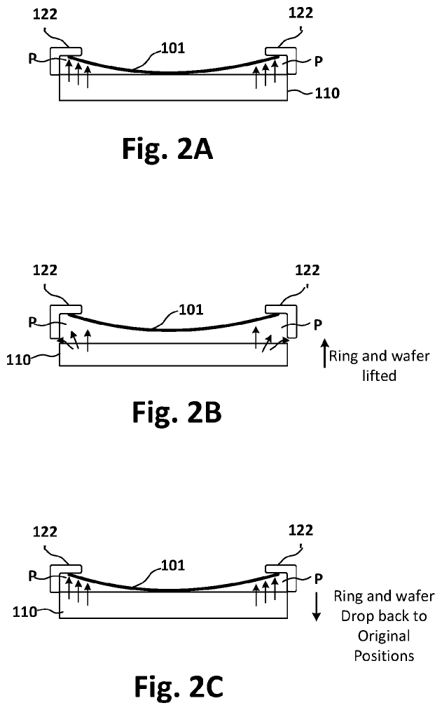

FIGS. 2A-2C are simplified schematic diagrams illustrating a problem that has been observed in the processing of bowed wafers. In the fabrication of 3D NAND devices, in which memory cells are stacked vertically in multiple layers, the increased presence of vertical structures relative to 2D/planar devices may create more stress on the wafer. This increased stress can cause wafers to bow or “dish” (turn slightly concave) during processing. In some cases, the degree of bowing can range from 0.25 millimeter to 0.75 millimeter relative to the center of the wafer. As such, when a bowed wafer rests on the pedestal, at least some points along the edge of the wafer may be 0.25 millimeters to 0.75 millimeters higher than the center of the wafer.

As shown in FIG. 2A, when a bowed wafer is processed, the edge of wafer 101 may contact the exclusion ring 122′. When the wafer edge gas starts to flow (as indicated by the arrows), the edge of the wafer 101 and the exclusion ring 122′ may create a seal that traps the wafer edge gas in the pocket P, which is the area bounded by the wafer 101, the pedestal 110, and the exclusion ring 122′. As the wafer edge gas continues to flow into the pocket P, the gas pressure within the pocket P may build up to a pressure sufficient to lift the exclusion ring 122′ and the wafer 101 from the surface of the pedestal 110, as shown in FIG. 2B. The lifting of the exclusion ring 122′ and the wafer 101 from the surface of the pedestal 110 may create a gap between the exclusion ring 122 and the surface of the pedestal 110 through which the trapped wafer edge gas can flow. As the wafer edge gas flows out of the pocket P through the thus-formed gap, the upward force on the exclusion ring 122′ and the wafer 101 may decrease, and the exclusion ring 122′ and the wafer 101 may drop back to their original positions, as shown in FIG. 2C. Once back in their original positions, the edge of the wafer 101 and the exclusion ring 122′ can create a seal again and thereby cause the lifting process shown in FIG. 2B to be repeated. Thus, during processing of a bowed wafer, this behavior may cause the exclusion ring 122′ to move up and down in rapid fashion relative to the surface of the pedestal 110. This up-and-down movement may be problematic because it not only causes wafer handling issues, but also results in unwanted deposition on the bevel and the backside of the wafer.

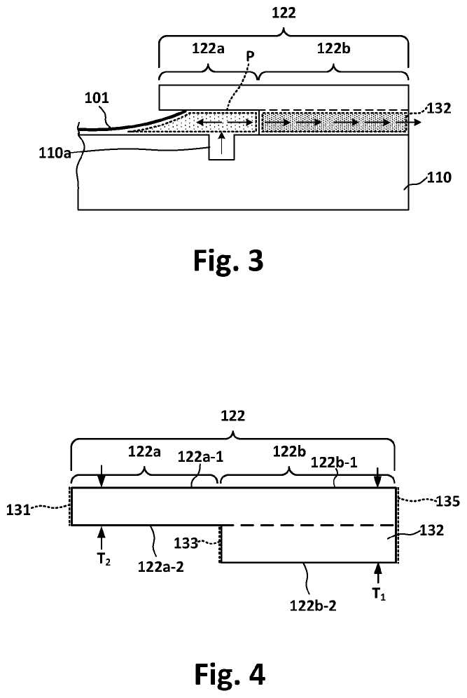

FIG. 3 is a simplified schematic diagram that shows an exclusion ring with a flow path, e.g., a slot, formed in the outer portion of the exclusion ring, in accordance with one embodiment. As shown in FIG. 3, the exclusion ring 122 may include a slot 132 formed within the outer circumferential portion (or segment) 122b of exclusion ring 122. The slot 132 may be configured to allow wafer edge gas that has accumulated in pocket P, which is the area bounded by the wafer 101, the pedestal 110, and the inner circumferential portion (or segment) 122a of exclusion ring 122, to flow out of the pocket P and into the chamber, e.g., outward toward the chamber walls, of the substrate processing system via the slot 132, as indicated by the arrows pointed toward the right in FIG. 3. Because the wafer edge gas can flow (or leak) out of the pocket P, the wafer edge gas pressure within the pocket P may not build up to a point sufficient to lift the exclusion ring 122 and the wafer 101 as shown in FIG. 2B. Thus, the up-and-down movement of the exclusion ring and wafer described above in connection with FIGS. 2A-2C may be prevented from occurring and the various issues associated therewith, e.g., unwanted deposition on the bevel and the backside of the wafer, are avoided.

FIG. 4 is a simplified cross-sectional diagram of an exclusion ring with a flow path, e.g., a slot, formed in the outer portion of the exclusion ring, in accordance with one embodiment. As shown in FIG. 4, the exclusion ring 122 includes inner circumferential portion (or segment) 122a and outer circumferential portion (or segment) 122b. The inner circumferential portion 122a has a top surface 122a-1 and a bottom surface 122a-2. Further, the inner circumferential portion 122a has a thickness, Tz, which is the distance between the top surface 122a-1 and the bottom surface 122a-2. The outer circumferential portion 122b has a top surface 122b-1 and a bottom surface 122b-2. Further, the outer circumferential portion 122b has a thickness, T₁, which is the distance between the top surface 122b-1 and the bottom surface 122b-2. The top surface 122a-1 of the inner circumferential portion 122a and the top surface 122b-1 of the outer circumferential portion 122b may define a common top surface for the exclusion ring 122; the common top surface of the exclusion ring 122 may be planar, as shown, or may, alternatively, feature a step or be contoured in some other manner, e.g., having a slight curve. Additionally, the thickness, T₁, of the outer circumferential portion 122b may be greater than the thickness, T₂, of the inner circumferential portion 122a. As such, when the bottom surface 122b-2 of the outer circumferential portion 122b rests on a pedestal, a gap may be defined between the bottom surface 122a-2 of the inner circumferential portion 122a and the pedestal, with the gap having a height sufficient to accommodate the edge of a wafer disposed on the pedestal for processing. Put another way, the bottom surfaces 122a-2 and 122b-2 may be offset from one another along an axis perpendicular to the bottom surface by a non-zero distance so as to form a space that provides the pocket. The slot 132 may extend through the outer circumferential portion 122b and thereby form a gas flow path from at least an intermediate circumferential perimeter 133 of the exclusion ring 122 to an exterior perimeter 135 of the exclusion ring 122 that provides for exhaust of a wafer edge gas from the pocket defined between the inner circumferential portion 122a and a pedestal. The intermediate circumferential perimeter 133 may generally be defined by reference circle that is either co-radial with, or inscribed within, the innermost edge or edges of the bottom surface 122b-2 of the outer circumferential portion 122b. A transition surface or transition surfaces may also span between the bottom surfaces 122a-2 and 122b-2, and may, in many implementations, be cylindrical or be co-radial arcuate surfaces, but may also, in some other implementations, be conical or co-radial arcuate conical surfaces (see FIG. 9, for example). In many, although not all, instances, the transition surface or surfaces may intersect with one or both of the bottom surfaces 122a-2 and 122b-2. In the case where the transition surface or surfaces directly intersect with the bottom surface 122b-2, the resulting intersection may generally define the intermediate circumferential perimeter 133. In the case where the transition surface or surfaces transition smoothly, e.g., with a blended or rounded edge, to the bottom surface 122b-2, the intermediate circumferential perimeter 133 may generally be inscribed in the innermost points where the bottom surface 122b-2 starts to become non-planar before then transitioning to the transition surface or surfaces. The exterior perimeter may generally be defined by the outermost perimeter of the exclusion ring and, in many implementations, circular, although it may also depart from a circular profile in some locations, e.g., in the locations where ears are provided (as discussed later). Similarly, the exclusion ring 122 may also have an interior perimeter 131 that is sized somewhat smaller than a wafer with which the exclusion ring 122 is designed to be used. The interior perimeter 131, for example, may be defined by the innermost surface or surfaces of the exclusion ring 122.

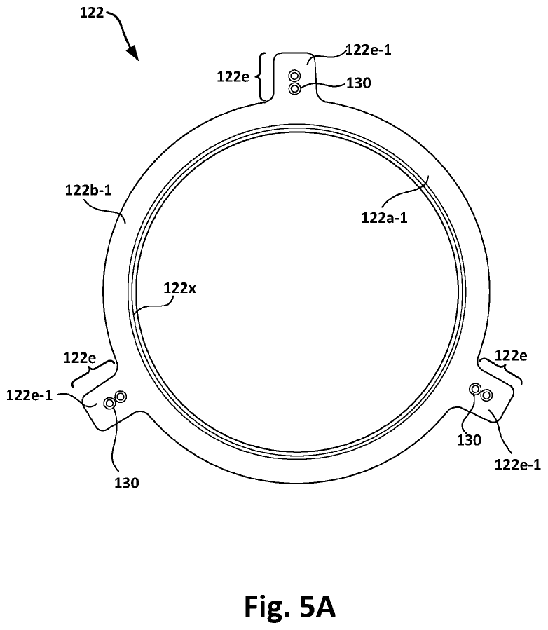

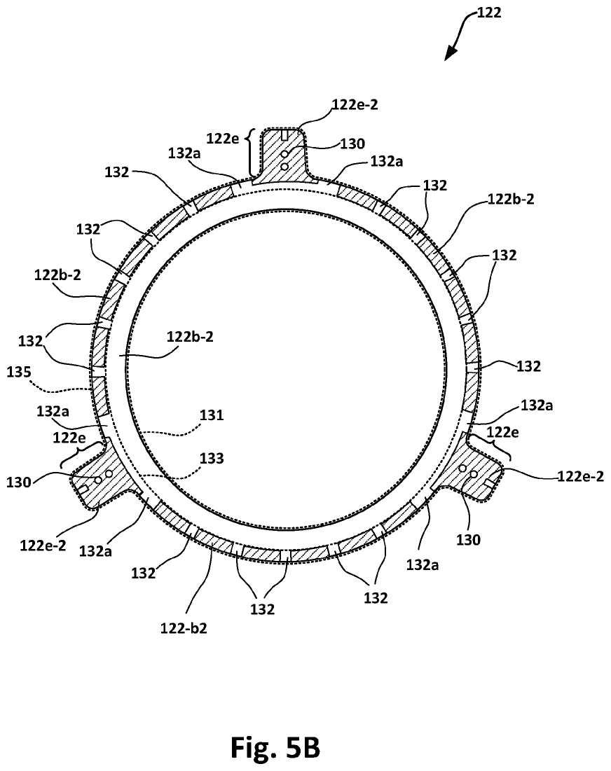

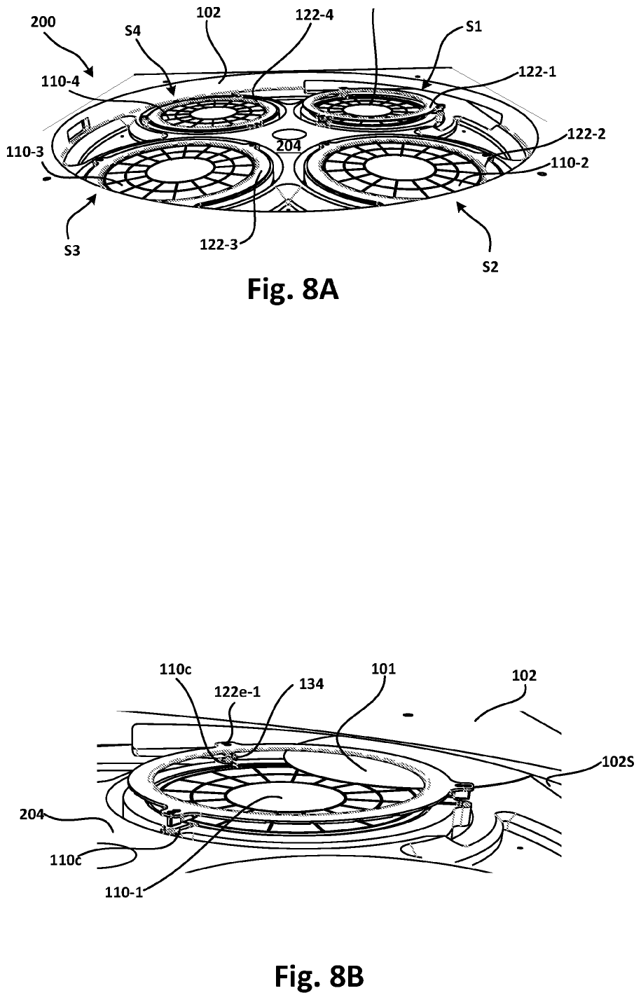

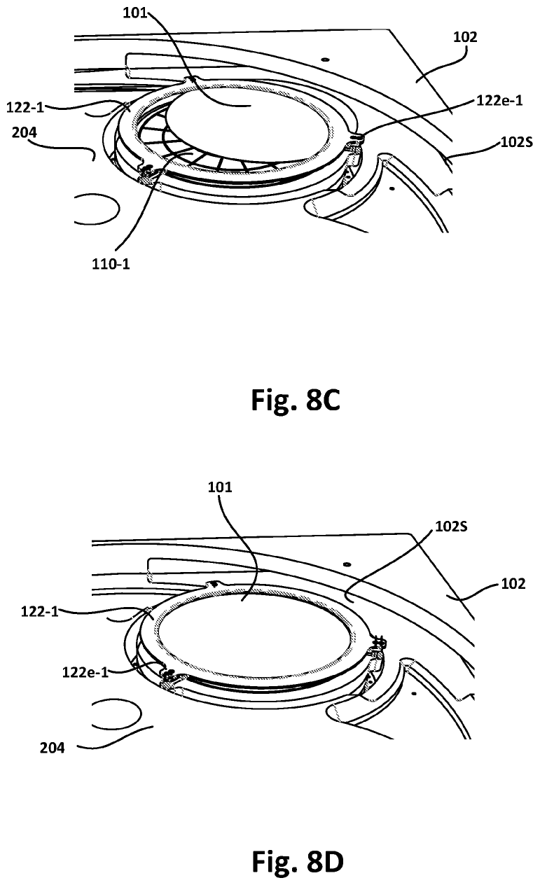

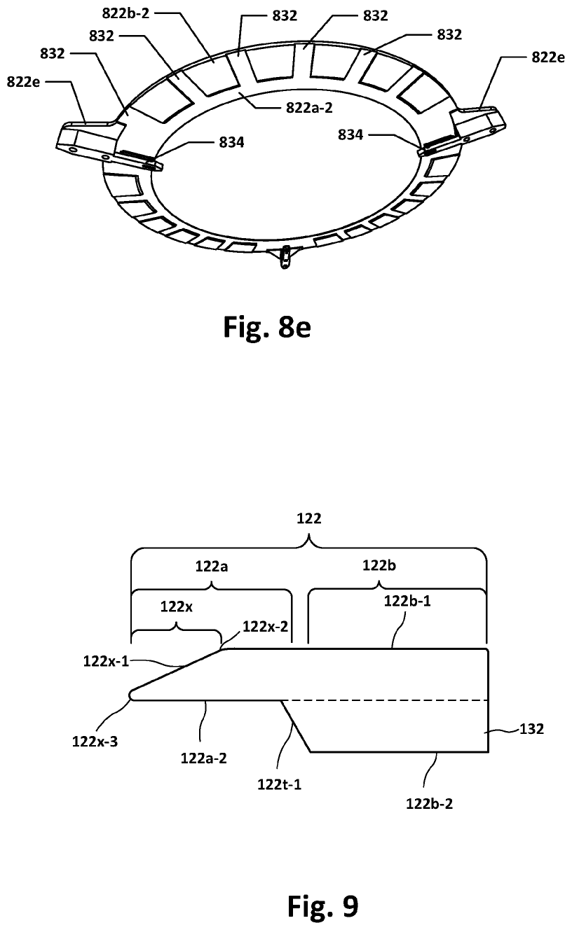

FIG. 5A is a top view of an exclusion ring having a plurality of slots formed within the outer circumferential portion thereof, in accordance with one embodiment. As shown in FIG. 5A, the top surface 122b-1 of the outer circumferential portion 122b and the top surface 122a-1 of the inner circumferential portion 112a may define a common top surface for the exclusion ring 122. A transition region 122x may be provided at the inner periphery of the exclusion ring 122 to minimize disruption of the flow of process gases during processing. Additional details regarding the transition region 122x are set forth below with reference to FIG. 9. A plurality of ears 122e may extend from the outer circumferential portion 122b, with each of the ears having a top surface 122e-1 and a bottom surface 122e-2 (see FIG. 5B). As shown in FIG. 5A, each of the ears 122e may include a pair of holes 130, which may be used to attach fingers to the ears 122e. Additional details regarding the fingers are set forth below with reference to FIGS. 8A-8D. In one embodiment, the holes 130 are threaded such that screws (or other suitable threaded mechanical fasteners) can be used to attach fingers to each of the ears 122e, as will be described in more detail below.

The exclusion ring 122 can be formed of any suitable material, provided the material is suitable for use within a plasma processing tool without introducing unwanted contamination, e.g., is chemically inert with respect to the processing gases and plasma used in the processing chamber. In one embodiment, the exclusion ring may be formed of alumina (Al₂O₃). In one embodiment, the alumina may have a purity of at least 99%. In another embodiment, the alumina may have a purity of at least 99.9%. It will be understood that the exclusion rings discussed herein may be manufactured using any suitable manufacturing technique, including both subtractive techniques in which material is removed from a larger piece of material and additive techniques in which the exclusion ring is built up gradually, e.g., from granular or liquid materials. In view of that, it is to be understood that references herein to “removed” material or the like are also intended to encompass the complement thereof in the context of an exclusion ring made using additive manufacturing techniques, i.e., “omitted” material or the like. Thus, a reference to “material removed” may be viewed as equivalent to “material omitted.”

In the example embodiment shown in FIG. 5A, the exclusion ring 122 includes three ears 122e and the three ears 122e are substantially evenly spaced around the outer circumferential portion 122b of the exclusion ring 122. In one embodiment, the respective centerlines of the ears 122e may be spaced around the outer circumferential portion 122b of the exclusion ring 122 at intervals of about 120 degrees. As used herein, the terms “about” and “approximately” mean that the specified parameter can be varied within a reasonable tolerance, e.g., ±10%. Those skilled in the art will appreciate that the number of ears as well as the spacing of the ears around the exclusion ring may be varied to meet the needs of particular applications.

FIG. 5B is a bottom view of an exclusion ring having a plurality of flow paths, e.g., slots, formed within the outer circumferential portion thereof, in accordance with one embodiment. As shown in FIG. 5B, the inner circumferential portion 122a of exclusion ring 122 has a bottom surface 122a-2 (generally located between the intermediate circumferential perimeter 133 (or within the intermediate circumferential perimeter 133) and the interior perimeter 131) and each of the ears 122e has a bottom surface 122e-2. The outer circumferential portion 122b has a bottom surface 122b-2 (generally located outside of the intermediate circumferential perimeter 133); however, the bottom surface 122b-2 is not a continuous surface in this example because this surface is interrupted by the presence of a plurality of slots 132 formed within the outer circumferential portion 122b to form the above-discussed flow paths. The slots in the plurality of slots 132 may be spaced apart along the periphery of the outer circumferential portion 122b. Further, the plurality of slots 132 may include slots 132a, which are the slots adjacent to the ears 122e. In one embodiment, the size, e.g., width, of slots 132a located next to the ears 122e (the adjacent slots) may be larger than the size of the slots 132 that are non-adjacent to the ears 122e (the non-adjacent slots). The increased size of the adjacent slots 132a relative to non-adjacent slots 132 may allow more wafer edge gas from the pocket to flow through the adjacent slots 132a to compensate for the larger amount of space that may be occupied by the ears 122e relative to that occupied by the segments of the outer circumferential portion 122b between the non-adjacent slots 132 or between one of the adjacent slots 132a and one of the non-adjacent slots 132. In one example embodiment, the width of the non-adjacent slots 132 may be approximately 9 mm, which may correspond to an arc of approximately 3 degrees for an exclusion ring sized for a 300 mm diameter wafer, and the width of the adjacent slots 132a may be approximately 20 mm, which may similarly correspond to an arc of approximately 6.5 degrees.

As shown in the example embodiment of FIG. 5B, the exclusion ring 122 may include a total of seven slots between each of the ears 122e. Each such set of seven slots may include five non-adjacent slots 132 and two adjacent slots 132a. Thus, an overall total of twenty-one slots may be spaced apart along the periphery of the outer circumferential portion 122b of the exclusion ring 122, with fifteen of the slots being non-adjacent slots 132 and six of the slots being adjacent slots 132a. Those skilled in the art will appreciate that the number of the slots, as well as the size of the slots, can be varied from that shown in FIG. 5B to meet the needs of particular applications. By way of example, in other embodiments, the exclusion ring 122 can include from three to sixteen slots between each of the ears 122e. In one embodiment, the exclusion ring 122 may include a total of five slots between each of the ears 122e, with three of the five slots being non-adjacent slots 132 and two of the five slots being adjacent slots 132a. In another embodiment, the exclusion ring 122 may include a total of nine slots between each of the ears 122e, with seven of the nine slots being non-adjacent slots 132 and two of the nine slots being adjacent slots 132a. In yet another embodiment, the exclusion ring 122 may include a total of fourteen slots between each of the ears 122e, with twelve of the fourteen slots being non-adjacent slots 132 and two of the fourteen slots being adjacent slots 132a.

In one example embodiment, the plurality of slots, which may include non-adjacent slots 132 and adjacent slots 132a, may be configured to satisfy the following two conditions: 1) to exhaust sufficient wafer edge gas from the pocket to eliminate any up-and-down movement of the exclusion ring (and wafer) during processing; and 2) to provide sufficient flow restriction so as to ensure that enough wafer edge gas remains in the pocket to prevent unwanted deposition from occurring on the bevel and backside of the wafer during processing. The amount of wafer edge gas that may need to be exhausted from the pocket to satisfy these two conditions may vary depending upon the processing conditions. For example, if the wafers being processed have a relatively high degree of bowing, then it might be desirable to exhaust more wafer edge gas from the pocket. On the other hand, if the wafers being processed have a relatively low degree of bowing, then it might be desirable to exhaust less wafer edge gas from the pocket. In example embodiments, the two conditions set forth above may be satisfied by controlling the ratio of the amount of wafer edge gas that is directed toward the wafer being processed to the amount of wafer edge gas that is exhausted from the pocket toward a chamber of the plasma processing tool, as will be described in more detail below.

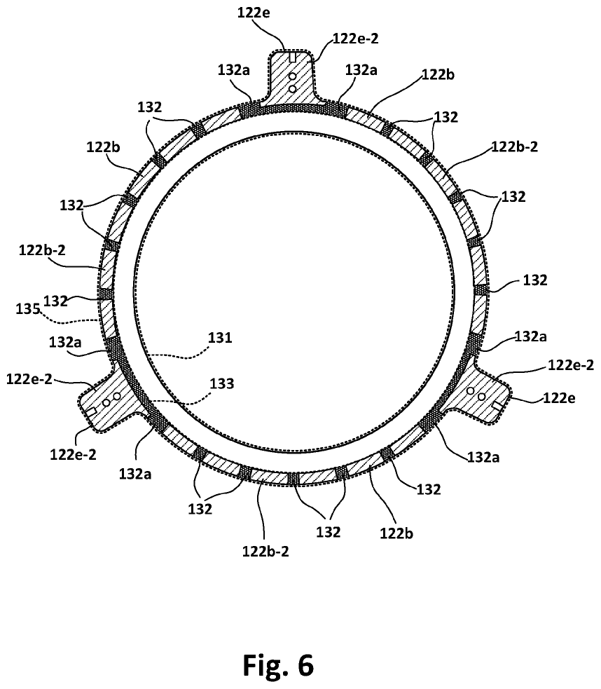

In one embodiment, the ratio of the amount of wafer edge gas that may be directed toward the wafer being processed to the amount of wafer edge gas that is exhausted from the pocket toward the chamber may be controlled by controlling the relative amount of material removed (or omitted) from the outer circumferential portion of the exclusion ring to form the plurality of slots. In particular, the area of the bottom surface of the outer circumferential portion that may be removed or omitted to form the plurality of slots may be controlled relative to the total ring bottom surface area. FIG. 6 is a bottom view of exclusion ring 122 that illustrates how the total ring bottom surface area is determined. The “hatched” sections shown in FIG. 6 include a) the bottom surface 122e-2 of each of the three ears 122e and b) the bottom surface 122b-2 of the outer circumferential portion 122b that remains after formation of the plurality of slots 132 (or that exists despite the slots 132). The “dark” sections shown in FIG. 6 include the portions of the bottom surface 122b-2 of the outer circumferential portion 122b that have been removed or omitted to form the plurality of slots 132. The “white” (no hatching) section shown in FIG. 6 includes the bottom surface 122a-2 of the inner circumferential portion 122a of exclusion ring 122. As used herein, the term “total ring bottom surface area” is a) the areas defined by the bottom surface 122e-2 of each of the ears 122e (these areas are part of the “hatched” area shown in FIG. 6), plus b) the area defined by the bottom surface 122b-2 of the outer circumferential portion 122b that remains after formation of the plurality of slots 132 (or that exists despite the slots 132) (this area is part of the “hatched” area shown in FIG. 6), plus c) the area of the bottom surface 122b-2 that has been removed from the outer circumferential portion 122b to form the plurality of slots 132 (or that otherwise is bounded by the slots 132) (the “dark” area shown in FIG. 6). Thus, the “white” (no hatching) area shown in FIG. 6, which includes the bottom surface 122a-2 of the inner circumferential portion 122a of exclusion ring 122, is not part of the total ring bottom surface area. Put another way, the total ring bottom surface area is the area between the intermediate circumferential perimeter 133 and the exterior perimeter 135.

In one example embodiment, the area of the bottom surface 122b-2 of the outer circumferential portion 122b that has been removed in this example to form the plurality of slots 132 may be in a range from about 16% to about 20% of the total ring bottom surface area. With this configuration, the plurality of slots may exhaust about 10% to about 30% of the wafer edge gas from the pocket toward the walls of a chamber of the plasma processing tool in which the exclusion ring 122 is being used. The remainder of the wafer edge gas may be directed toward a wafer when present in the plasma processing tool. In one embodiment, the area of the bottom surface of the outer circumferential portion that may be cut out to form the plurality of slots may be about 18% of the total ring bottom surface area. With this configuration, about 20% of the wafer edge gas may be exhausted toward the walls of a chamber in which the exclusion ring 122 is being used and about 80% of the wafer edge gas may be directed toward the wafer.

In another example embodiment, the area of the bottom surface 122b-2 of the outer circumferential portion 122b that has been removed to form the plurality of slots 132 may be in a range from about 23% to about 28% of the total ring bottom surface area. With this configuration, the plurality of slots may exhaust about 40% to about 60% of the wafer edge gas from the pocket toward the walls of a chamber of the plasma processing tool in which the exclusion ring 122 is being used. The remainder of the wafer edge gas may be directed inward toward a wafer when present in the plasma processing tool. In one embodiment, the area of the bottom surface of the outer circumferential portion that may be cut out to form the plurality of slots may be about 25% of the total ring bottom surface area. With this configuration, about 50% of the wafer edge gas may be exhausted toward the walls of a chamber in which the exclusion ring 122 is being used and about 50% of the wafer edge gas may be directed inward toward the wafer.

In yet another example embodiment, the area of the bottom surface 122b-2 of the outer circumferential portion 122b that may be removed to form the plurality of slots 132 may be in a range from about 35% to about 43% of the total ring bottom surface area. With this configuration, the plurality of slots may exhaust about 70% to about 90% of the wafer edge gas from the pocket toward the walls of a chamber of the plasma processing tool in which the exclusion ring 122 is being used. The remainder of the wafer edge gas may be directed inward toward a wafer when present in the plasma processing tool. In one embodiment, the area of the bottom surface of the outer circumferential portion that may be cut out to form the plurality of slots may be about 39% of the total ring bottom surface area. With this configuration, about 80% of the wafer edge gas may be exhausted toward the walls of a chamber in which the exclusion ring 122 is being used and about 20% of the wafer edge gas may be directed inward toward the wafer.

During processing of a wafer in a chamber, the space above the wafer and the exclusion ring may be a relatively high-pressure region compared to other locations within the chamber that are not similarly above a wafer and exclusion ring because of the presence of the process gases, and the space around the outside of the pedestal and the exclusion ring may correspondingly be a relatively low-pressure region. Thus, when the pressure of the wafer edge gas builds up within the pocket, the wafer edge gas may tend to leak from the pocket through the slots because the space to the outside of the exclusion ring and the pedestal is a relatively low-pressure region. In wafer processing operations using exclusion rings having a plurality of slots configured as described in the example embodiments above, bowed wafers have been processed without any significant deposition on the edge bevel or the backside of the wafer at wafer edge gas flow rates up to 2500 sccm. In light of the absence of any significant deposition on the bevel or the backside of the wafer, it is believed that no up-and-down movement of the exclusion ring and the wafer occurred during processing, because such movement would inevitably have resulted in unwanted deposition on the bevel and/or the backside of the wafer. As such, the configurations of the slots in the exclusion rings of the example embodiments described herein satisfy the above-mentioned two conditions, namely 1) to exhaust sufficient wafer edge gas from the pocket to eliminate any up-and-down movement of the exclusion ring (and wafer) during processing; and 2) to provide sufficient flow restriction so as to ensure that enough wafer edge gas remains in the pocket to prevent unwanted deposition from occurring on the bevel and backside of the wafer during processing.

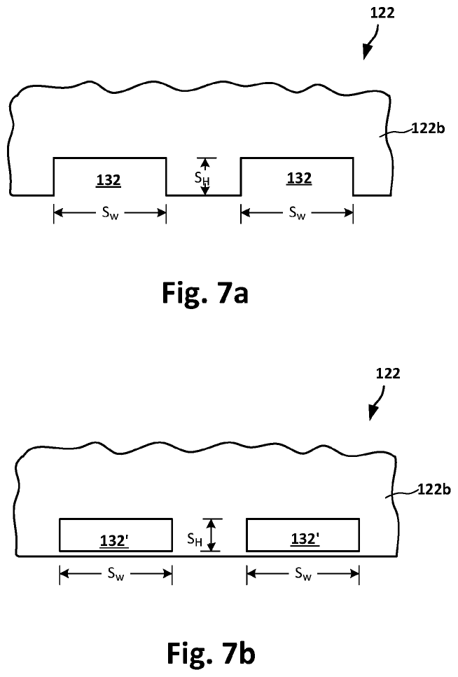

FIG. 7a is a simplified partial front or side view of the slots formed within the outer circumferential portion of the exclusion ring, in accordance with one embodiment. As shown in FIG. 7a, slots 132 formed within the outer circumferential portion 122b of exclusion ring 122 may have a slot width, S_{w}, and a slot height, Sₕ. In one embodiment, the slot width, S_{w}, may be in a range from about 0.100 inch to about 0.760 inch. In one embodiment, the slot height, Sₕ, may be in a range from about 0.010 inch to about 0.040 inch. It will be appreciated by those skilled in the art that the slot heights and slot widths can be varied to meets the needs of particular applications.

FIG. 7b is a simplified partial front or side view of enclosed passages formed within the outer circumferential portion of the exclusion ring, in accordance with another embodiment. As can be seen in FIG. 7b, the enclosed passages 132′ may also have a width and height which may have dimensions similar to those discussed above with respect the slot width S_{w} and the slot height Sₕ of FIG. 7a.

It will be understood that the slots 132 or the enclosed passages 132′ used in the example exclusion rings of FIGS. 7a and 7b may generally represent flow paths, as discussed earlier herein, that may be used to provide exhaust of wafer edge gas from the pocket to prevent exclusion ring lift. The slots 132 may generally be more easily manufactured, as they may simply be machined or formed into the underside of the exclusion ring, but it is to be recognized that exclusion rings with equivalent or similar performance that use enclosed passages may also be used. Such exclusion rings may be more complicated and expensive to manufacture, e.g., using additive manufacturing or through diffusion bonding different parts together, but may still perform in a similar manner. As such, references to “slots” herein are to be understood to similarly apply to “enclosed passages,” including, but not limited to, references to the number of slots, the placement of slots, the relative sizes of slots, etc. In the context of enclosed passages 132′, there may not be any area of the bottom surface 122b-2 of the outer circumferential portion 122b that has been removed or omitted, but it will be understood that an equivalent area exists in the sum of the cross-sectional areas of all of the enclosed passages 132′ of an exclusion ring, each cross-sectional area taken in a plane parallel to the bottom surface 122b-2. It is to be understood that this cross-sectional area sum may be substituted for the area of the bottom surface 122b-2 that has been removed or omitted in the discussion provided herein. Moreover, the total ring bottom surface area of such an exclusion ring may simply be the area defined by the bottom surface of each of the three ears plus an area defined by the bottom surface of the outer circumferential segment since the bottom surface of the outer circumferential segment would not be interrupted by slots due to the use of enclosed passages.

FIGS. 8A-8D illustrate use of the exclusion ring in a multi-station plasma processing tool, in accordance with one embodiment. FIG. 8A shows a perspective view of a multi-station plasma processing tool having four processing stations. In particular, as shown in FIG. 8A, multi-station plasma processing tool 200 includes four processing stations, S1-S4, within chamber 102. Each processing station may include a pedestal 110, which is fixed, and an exclusion ring 122, which can be moved from station to station along with a wafer being supported by the exclusion ring. For example, as shown in FIG. 8A, processing station S1 includes pedestal 110-1 and exclusion ring 122-1. Turntable 204 may be used to transfer wafers from one station to another station, as will be described in more detail below. In one embodiment, the turntable 204 may be an aluminum plate.

FIGS. 8B-8D illustrate the process of loading a wafer into the multi-station plasma processing tool, in accordance with one embodiment. As shown in FIG. 8B, wafer 101 is in the process of passing through slot 102s in chamber 102. The slot 102s may be coupled to a load lock outside of chamber 102 so that the vacuum environment within the chamber may be maintained during the loading process. As the wafer 101 enters the chamber 102 through the slot 102s, the exclusion ring 122-1 may be in a raised position in which fingers 134, which are attached to each of ears 122e-1, may be positioned above the top surface of pedestal 110-1. The fingers 134 may extend inside the inner periphery of the exclusion ring 122-1, and the wafer 101 may be supported by the end effector at a height that enables the wafer 101 to pass just over the fingers 134 without contacting either the fingers 134 or the exclusion ring 122-1, as can be seen in FIG. 8C. Once the wafer 101 is positioned so that the outer periphery of the wafer 101 is situated above each of the three fingers 134, as shown in FIG. 8D, the end effector may lower the wafer 101 onto the fingers 134 and may be withdrawn from the chamber 102. At this point, the exclusion ring 122-1 can be lowered to place the wafer 101 on the top surface of the pedestal 110-1. To enable the wafer 101 to be placed on the top surface of the pedestal 110-1, the fingers 134 may be received in grooves or recesses 110c (see FIG. 8B) that extend below the top surface of the pedestal 110-1 as the exclusion ring 122-1 is lowered.

To transfer a wafer from one station to another, e.g., from station S1 to station S2, exclusion ring 122-1 may be raised by a vertical translation system to lift the wafer 101 from the top surface of the pedestal 110-1. For example, as the exclusion ring 122-1 is raised, the fingers 134 emerge from within the grooves or recesses 110c in the pedestal 110-1 and engage with the backside of the wafer 101. Thus, once the fingers 134 engage with the backside of the wafer 101, the wafer 101 may be raised along with the exclusion ring 122-1. With the wafer 101 supported above the top surface of the pedestal 110-1 by the exclusion ring 122-1, the turntable 204 may then be raised from a standard position to a raised position. In the process of being raised, the turntable 204 may engage with the exclusion ring 122-1 and may lift the exclusion ring 122-1, as well as wafer 101 being supported by the exclusion ring 122-1. Once the turntable 204, the exclusion ring 122-1, and the wafer 101 have been raised to a point high enough for all to clear the pedestal 110-1 and the vertical translation system at station S1, the turntable 204 may be rotated so that exclusion ring 122-1 and wafer 101 are carried from station S1 to station S2. At station S2, the exclusion ring 122-1 may be placed onto the vertical translation system of station S2, as part of the process of lowering the turntable 204 back to its standard position.

In some of the example embodiments described herein, e.g., the example embodiment of FIGS. 8A-8D, the fingers 134 of exclusion ring 122-1 may be used to carry the wafer 101 from station to station, e.g., station S1 to station S2. As such, the exclusion ring 122-1 might also be considered to be a “carrier ring.” Nevertheless, in the description of the example embodiments, the exclusion ring 122-1 is referred to an “exclusion ring” rather than a “carrier ring” because the primary function of the ring is to prevent deposition on the bevel and the backside of the wafer during processing.

FIG. 8E depicts a perspective view of the underside of an example exclusion ring. As can be see, the underside of the exclusion ring has an inner circumferential portion with a bottom surface 122a-2 and an outer circumferential portion with a bottom surface 122b-2. A plurality of openings 832, e.g., slots, are arranged around the perimeter of the exclusion ring, and three ears 822e are located at evenly spaced locations about the periphery of the outer circumferential portion. Each ear 822e may support a finger 834, as discussed above with respect to FIGS. 8A through 8D.

FIG. 9 is a simplified cross-sectional diagram that shows additional details of an exclusion ring with a slot formed in the outer portion of the exclusion ring, in accordance with one embodiment. As shown in FIG. 9, the inner periphery of inner circumferential portion 122a of exclusion ring 122 may include transition region 122x. As stated above in connection with the description of FIG. 5A, the transition region 122x may serve to minimize disruption of the flow of process gases by the exclusion ring 122 during processing. The transition region 122x may include a sloped region 122x-1, a curved region 122x-2, and a tip region 122x-3. The curved region 122x-2 may extend from the top surface 122a-1 of the inner circumferential portion 122 to the sloped region 122x-1. In one embodiment, the curved region 122x-2 may have a radius of curvature. In one embodiment, the radius of curvature of the curved region 122x-2 may be in a range from 12 inches to 12.25 inches. The sloped region 122x-1 may extend from the curved region 122x-2 to the tip region 122x-3. In one embodiment, the surface of the sloped region 122x-1 may define an angle in a range from about 15 degrees to about 45 degrees relative to a plane defined by the top surface 122a-1 of inner circumferential portion 122a of exclusion ring 122. The tip region 122x-3 may be configured to have sufficient strength to withstand use in a tool without chipping or otherwise breaking off. In one embodiment, the tip region 122x-3 may have a radius of curvature selected to provide the tip region with the needed strength without disrupting the flow of process gases by the exclusion ring 122 during processing.

In one embodiment, a transition surface 122t-1 that extends between the bottom surface 122a-2 and the bottom surface 122b-2 may be sloped to minimize disruption of the flow of the wafer edge gas as the wafer edge gas is exhausted from the pocket through slots 132 within the outer circumferential portion 122b of the exclusion ring 122. As shown in FIG. 9, the transition surface 122t-1 and the bottom surface 122a-2 may define between them an included angle that is an obtuse angle. In one embodiment, the obtuse angle defined by the transition surface 122t-1 and the bottom surface 122a-2 may be in a range from about 105 degrees to about 150 degrees.

The embodiments described herein may also include a method of processing a wafer in a plasma processing tool. The method may include positioning an exclusion ring on or over a pedestal of a chamber. In one embodiment, the exclusion ring may be positioned such that an outer circumferential portion of the exclusion ring sits over the pedestal and an inner circumferential portion of the exclusion ring is spaced apart from the pedestal to define a pocket between the exclusion ring and the pedestal where a wafer has an edge thereof disposed below part of the inner circumferential portion (see, for example, FIG. 3). The method may also include supplying a wafer edge gas into the pocket during plasma processing of the wafer such that a portion of the wafer edge gas is directed toward the wafer. In one embodiment, the wafer edge gas may be fed into the pocket through an edge gas groove formed in the pedestal (see, for example, edge gas groove 110a in FIGS. 1 and 3). The method may further include exhausting a portion of the wafer edge gas from the pocket toward the walls of a chamber in which the wafer processing is performed through a plurality of flow paths that extend through the outer circumferential portion of the exclusion ring (see, for example, slot 132 shown in FIG. 3 and slots 132 and 132a shown in FIG. 5B).

In one embodiment, the plurality of flow paths is configured to exhaust about 10% to about 30% of the wafer edge gas from the pocket toward the walls of the chamber in which the wafer processing is performed, with a remaining portion of the wafer edge gas being directed inward toward the wafer. As described above, the ratio of the amount of wafer edge gas that is directed toward the wafer being processed to the amount of wafer edge gas that is exhausted from the pocket toward the chamber walls can be adjusted by controlling the relative amount of material removed or omitted from the outer circumferential portion of the exclusion ring to form the plurality of flow paths. In particular, the area of the bottom surface of the outer circumferential portion that has been removed or omitted to form the plurality of flow paths may be controlled relative to the total ring bottom surface area. To exhaust about 10% to about 30% of the wafer edge gas from the pocket toward the walls of the chamber, in one example embodiment, the area of the bottom surface 122b-2 of the outer circumferential portion 122b that has been removed to form the plurality of slots 132 may be in a range from about 16% to about 20% of the total ring bottom surface area (see FIG. 6). In one embodiment, the area of the bottom surface of the outer circumferential portion that is cut out to form the plurality of slots may be about 18% of the total ring bottom surface area. With this configuration, about 20% of the wafer edge gas may be exhausted toward the walls of the chamber and about 80% of the wafer edge gas may be directed toward the wafer.

In one embodiment, the plurality of slots may be configured to exhaust about 40% to about 60% of the wafer edge gas from the pocket toward the walls of the chamber, with a remaining portion of the wafer edge gas being directed inward toward the wafer. To exhaust about 40% to about 60% of the wafer edge gas from the pocket toward the walls of the chamber, in one example embodiment, the area of the bottom surface 122b-2 of the outer circumferential portion 122b that has been removed to form the plurality of slots 132 may be in a range from about 23% to about 28% of the total ring bottom surface area (see FIG. 6). In one embodiment, the area of the bottom surface of the outer circumferential portion that is cut out to form the plurality of slots may be about 25% of the total ring bottom surface area. With this configuration, about 50% of the wafer edge gas may be exhausted toward the chamber and about 50% of the wafer edge gas may be directed toward the wafer.

In one embodiment, the plurality of slots may be configured to exhaust about 70% to about 90% of the wafer edge gas from the pocket toward the chamber, with a remaining portion of the wafer edge gas being directed toward the wafer. To exhaust about 70% to about 90% of the wafer edge gas from the pocket toward the chamber, in one example embodiment, the area of the bottom surface 122b-2 of the outer circumferential portion 122b that has been removed to form the plurality of slots 132 may be in a range from about 35% to about 43% of the total ring bottom surface area (see FIG. 6). In one embodiment, the area of the bottom surface of the outer circumferential portion that may be cut out to form the plurality of slots may be about 39% of the total ring bottom surface area. With this configuration, about 80% of the wafer edge gas may be exhausted toward the chamber and about 20% of the wafer edge gas may be directed toward the wafer.

In some implementations, a controller that is part of a system may be part of some of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system. In particular, the controller may be configured to cause, for example, a lift mechanism to lift an exclusion ring (and wafer supported thereby) and a turntable to then lift the exclusion ring and rotate so as to move the exclusion ring to a new station within a multi-station processing chamber, as discussed earlier herein. The controller may be further configured to then lower the exclusion ring onto or into the new station.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Although method operations may be described in a specific order, it should be understood that other housekeeping operations may be performed in between operations, or operations may be adjusted so that they occur at slightly different times, or may be distributed in a system which allows the occurrence of the processing operations at various intervals associated with the processing, as long as the processing of the overlay operations are performed in the desired way.

Accordingly, the disclosure of the example embodiments is intended to be illustrative, but not limiting, of the scope of the disclosures, which are set forth in the following claims and their equivalents. Although example embodiments of the disclosures have been described in some detail for purposes of clarity of understanding, it will be apparent that certain changes and modifications can be practiced within the scope of the following claims. In the following claims, elements and/or steps do not imply any particular order of operation, unless explicitly stated in the claims or implicitly required by the disclosure.

1. An exclusion ring for use in processing semiconductor wafers, the exclusion ring comprising:
an outer circumferential segment with a top surface and a bottom surface, wherein a distance between the top surface of the outer circumferential segment and the bottom surface of the outer circumferential segment defines a first thickness of the exclusion ring;
an inner circumferential segment with a top surface and a bottom surface; and
one or more transition surfaces that span between the bottom surface of the outer circumferential segment and the bottom surface of the inner circumferential segment, wherein:
a distance between the top surface of the inner circumferential segment and the bottom surface of the inner circumferential segment defines a second thickness of the exclusion ring,
the first thickness of the exclusion ring is greater than the second thickness of the exclusion ring; and
a plurality of flow paths formed within the outer circumferential segment, wherein:
each flow path of the plurality of flow paths extends from the one or more transition surfaces, through the outer circumferential segment of the exclusion ring, and to an exterior perimeter of the exclusion ring, and
the flow paths are spaced apart from one another along a periphery of the outer circumferential segment of the exclusion ring.

2. The exclusion ring of claim 1, further comprising:
a plurality of ears, wherein each of the ears extends from the outer circumferential segment of the exclusion ring and has a top surface and a bottom surface; and
a plurality of fingers, wherein each of the fingers is attached to a respective one of the plurality of ears.

3. The exclusion ring of claim 2, wherein the plurality of ears includes three ears that are substantially evenly spaced around the outer circumferential segment of the exclusion ring, and wherein the plurality of flow paths includes a number of flow paths between each of the three ears and the number of flow paths is in a range from three to sixteen.

4. The exclusion ring of claim 3, wherein a same number of flow paths is through the outer circumferential segment between each of the three ears.

5. The exclusion ring of claim 4, wherein seven to fourteen flow paths are formed through the outer circumferential segment between each of the three ears.

6. The exclusion ring of claim 3, wherein the flow paths that are proximate to each of the three ears are sized larger than the flow paths that are not proximate to any of the three ears.

7. The exclusion ring of claim 3, wherein:
the inner circumferential segment has an innermost edge that is axisymmetric about a center axis, and
a total cross-sectional area of the flow paths in a first reference plane that is perpendicular to the center axis and interposed between the bottom surfaces of the inner circumferential segment and the outer circumferential segment is in a range from about 16% to about 20% of a total ring bottom surface area that is defined between the outer perimeter of the exclusion ring and a reference circle that circumscribes the one or more transition surfaces.

8. The exclusion ring of claim 7, wherein the total cross-sectional area of the flow paths in the first reference plane is in a range from about 23% to about 28% of the total ring bottom surface area.

9. The exclusion ring of claim 7, wherein the total cross-sectional area of the flow paths in the first reference plane is in a range from about 35% to about 43% of the total ring bottom surface area.

10. The exclusion ring of claim 1, wherein each of the flow paths is selected from the group consisting of: a) channels in the bottom surface of the outer circumferential segment and b) enclosed passages through the outer circumferential segment.

11. An exclusion ring, comprising:
an inner circumferential portion; and
an outer circumferential portion integral with the inner circumferential portion, wherein:
the outer circumferential portion has a first thickness that is greater than a second thickness of the inner circumferential portion, wherein a bottom surface of the outer circumferential portion is configured to be placed over a pedestal when installed in a plasma processing tool,
the inner circumferential portion is configured to be spaced apart from the pedestal when the bottom surface of the outer circumferential portion is resting on the pedestal of the plasma processing tool, thereby defining a pocket in between the pedestal and the exclusion ring that permits an edge of a wafer, when present, to be disposed in between part of the inner circumferential portion and the pedestal, and
the outer circumferential portion includes a plurality of flow paths, wherein each flow path extends from one or more transition surfaces that span between the bottom surface of the outer circumferential portion and a bottom surface of the inner circumferential portion, through the outer circumferential portion, and to an outer perimeter of the exclusion ring to provide for exhaust of a wafer edge gas from the pocket.

12. The exclusion ring of claim 11, further comprising:
a plurality of ears, wherein each of the ears extends from the outer circumferential portion of the exclusion ring; and
a plurality of fingers, wherein each of the fingers is attached to a respective one of the plurality of ears.

13. The exclusion ring of claim 12, wherein:
the plurality of ears includes three ears,
the three ears are substantially evenly spaced around the outer circumferential portion of the exclusion ring, and
the plurality of flow paths includes a number of flow paths between each of the three ears.

14. The exclusion ring of claim 13, wherein the flow paths proximate to each of the three ears are sized larger than the flow paths that are not proximate to any of the three ears.

15. The exclusion ring of claim 13, wherein the plurality of flow paths is configured to exhaust about 10% to about 30% of the wafer edge gas from the pocket toward a chamber wall of the plasma processing tool such that a remainder of the wafer edge gas is directed toward the edge of the wafer when the wafer is present in the pocket and the wafer edge gas is flowing.

16. The exclusion ring of claim 13, wherein the plurality of flow paths is configured to exhaust about 40% to about 60% of the wafer edge gas from the pocket toward a chamber wall of the plasma processing tool such that a remainder of the wafer edge gas is directed toward the edge of the wafer when the wafer is present in the pocket and the wafer edge gas is flowing.

17. The exclusion ring of claim 13, wherein the plurality of flow paths is configured to exhaust about 70% to about 90% of the wafer edge gas from the pocket toward a chamber wall of the plasma processing tool such that a remainder of the wafer edge gas is directed toward the edge of the wafer when the wafer is present in the pocket and the wafer edge gas is flowing.

18. The exclusion ring of claim 11, wherein each of the flow paths is selected from the group consisting of: a) channels in the bottom surface of the outer circumferential portion and b) enclosed passages through the outer circumferential portion.

19. A method of processing a wafer in a plasma processing tool, comprising:
positioning an exclusion ring such that an outer circumferential portion of the exclusion ring sits on a pedestal of a chamber and an inner circumferential portion of the exclusion ring is spaced apart from the pedestal to define a pocket where a wafer has an edge thereof disposed below part of the inner circumferential portion;
supplying a wafer edge gas into the pocket during plasma processing of the wafer such that a portion of the wafer edge gas is directed toward the wafer; and
exhausting a portion of the wafer edge gas from the pocket toward the chamber through a plurality of flow paths that extend through the outer circumferential portion of the exclusion ring.

20. The method of claim 19, wherein the plurality of flow paths is configured to exhaust an amount of wafer edge gas from the pocket toward the chamber, with a remaining portion of the wafer edge gas being directed toward the wafer, wherein the amount is selected from the group consisting of: about 10% to about 30% of the wafer edge gas, about 40% to 60% of the wafer edge gas, and about 70% to about 90% of the wafer edge gas.
